(19) United States
(12) Patent Application Publication
(10) Pub. No.: US 2020/0195221 A1
(43) Pub. Date: Jun. 18, 2020

(54) PIEZOELECTRIC THIN FILM RESONATOR

(71) Applicant: WISOL CO., LTD., Osan-si (KR)

(72) Inventors: Yong Hun KO, Osan-si (KR); Duck Hwan KIM, Osan-si (KR); Jong Hyeon PARK, Osan-si (KR)

(21) Appl. No.: 16/705,500

(22) Filed: Dec. 6, 2019

(30) Foreign Application Priority Data
Dec. 13, 2018 (KR) 10-2018-0161000

(51) Int. Cl. H03H 9/13; H03H 9/17

(52) U.S. Cl. CPC H03H 9/132; H01L 41/0533; H03H 9/173

(57) ABSTRACT

A piezoelectric thin film resonator includes: a wafer; a lower electrode positioned on top of the wafer; a piezoelectric layer positioned on top of the lower electrode; and an upper electrode positioned on top of the piezoelectric layer, wherein the upper electrode has concavo-convex patterns formed on top thereof in such a manner as to surround a resonance area formed thereon.

### CROSS REFERENCE TO RELATED APPLICATION

The present application claims the benefit of Korean Patent Application No. 10-2018-0161000 filed in the Korean Intellectual Property Office on Dec. 13, 2018, the entire content of which is incorporated herein by reference.

### Field of the Invention

### BACKGROUND OF THE INVENTION

### 1. Field of the Invention

The present invention relates to a piezoelectric thin film resonator, and more particularly, to a piezoelectric thin film resonator that is capable of allowing various concavo-convex patterns to be formed on an upper electrode thereof, thereby improving resonance characteristics thereof.

### 2. Description of Related Art

As mobile communication devices, chemical and bio devices, and the like have been rapidly developed, recently, demands for a small and lightweight filter, an oscillator, a resonant element, and an acoustic resonant mass sensor used in the communication devices have increased.

So as to implement functions of the small and lightweight filter, the oscillator, the resonant element, and the acoustic resonant mass sensor, a film bulk acoustic resonator (hereinafter, referred to as “FBAR”) has been used.

The FBAR is an element that can be produced in mass quantities at minimal cost and can be also ultra-small in size, advantageously. In addition, the FBAR can improve a quality factor (Q) value as one of main characteristics of a filter and especially can provide bands of PCS (Personal Communication System) and a DCS (Digital Cordless System).

The FBAR includes a wafer, a lower electrode positioned on the wafer, a piezoelectric layer positioned on the lower electrode, and an upper electrode positioned on the piezoelectric layer, and in this case, a frame or additive film is laid on the upper electrode so as to improve the resonance characteristics of the FBAR.

If a filter is combined with the resonator having the frame or additive film laid on the upper electrode, however, spurious noise is not completely suppressed, insertion loss increases, and a band of the filter is reduced, disadvantageously.

Accordingly, there is a definite need for development of a piezoelectric thin film resonator capable of decreasing spurious noise and improving resonance characteristics.

### SUMMARY OF THE INVENTION

Accordingly, the present invention has been made in view of the above-mentioned problems occurring in the related art, and it is an object of the present invention to provide a piezoelectric thin film resonator that is configured to have given patterns formed on an upper electrode, thereby improving a value of an electromechanical coupling factor K² and reducing spurious noise.

It is another object of the present invention to provide a piezoelectric thin film resonator that is capable of being made through a simple manufacturing process, while improving resonance characteristics of the resonator inserted into a filter.

The technical problems to be achieved through the present invention are not limited as mentioned above, and other technical problems not mentioned herein will be obviously understood by one of ordinary skill in the art through the following description.

To accomplish the above-mentioned objects, according to the present invention, there is provided a piezoelectric thin film resonator including: a wafer: a lower electrode positioned on top of the wafer; a piezoelectric layer positioned on top of the lower electrode; and an upper electrode positioned on top of the piezoelectric layer, wherein the upper electrode has concavo-convex patterns formed on top thereof in such a manner as to surround a resonance area formed thereon.

According to the present invention, desirably, the concavo-convex patterns include first patterns having shapes of a plurality of loops in such a manner as to surround a periphery of the resonance area.

According to the present invention, desirably, resonance frequencies of the piezoelectric thin film resonator are varied according to thicknesses or distances of the first patterns having the shapes of the plurality of loops.

According to the present invention, desirably, the concavo-convex patterns include second patterns having shapes of a plurality of islands in such a manner as to surround a periphery of the resonance area.

According to the present invention, desirably, the concavo-convex patterns further include a pattern having a shape of a loop in such a manner as to surround the second patterns having the shapes of the plurality of islands.

According to the present invention, desirably, resonance frequencies of the piezoelectric thin film resonator are varied according to sizes or densities of the second patterns having the shapes of the plurality of islands.

According to the present invention, desirably, a ratio of a vertical height of the first patterns to a vertical height of the upper electrode is 1:20 to 3:10.

According to the present invention, desirably, a vertical height of the concavo-convex patterns formed along the outermost periphery of the resonance area is higher than vertical heights of the concavo-convex patterns formed along the inner side of the resonance area.

According to the present invention, desirably, the piezoelectric thin film resonator further includes a protection layer positioned on top of the upper electrode to cover an area where the concavo-convex patterns are formed.

According to the present invention, desirably, the piezoelectric thin film resonator further includes a seed layer formed between the wafer and the lower electrode.

### BRIEF DESCRIPTION OF THE DRAWINGS

The above and other objects, features and advantages of the present invention will be apparent from the following detailed description of the embodiments of the invention in conjunction with the accompanying drawings, in which:

FIGS. 1A and 1B are sectional and top views showing a piezoelectric thin film resonator according to a first embodiment of the present invention;

FIGS. 2A and 2B are top and sectional views showing a piezoelectric thin film resonator according to a second embodiment of the present invention;

FIGS. 3A to 3F are top views showing various thicknesses and distances of concavo-convex patterns on an upper electrode of the piezoelectric thin film resonator according to the first embodiment of the present invention;

FIGS. 4A to 4E are top views showing examples of concavo-convex patterns on an upper electrode of a piezoelectric thin film resonator according to a third embodiment of the present invention;

FIG. 5 is a top view showing concavo-convex patterns on an upper electrode of a piezoelectric thin film resonator according to a fourth embodiment of the present invention;

FIG. 6 is a sectional view showing a piezoelectric thin film resonator according to a fifth embodiment of the present invention;

FIG. 7 is a sectional view showing a piezoelectric thin film resonator according to a sixth embodiment of the present invention; and

FIG. 8 is a sectional view showing a piezoelectric thin film resonator according to a seventh embodiment of the present invention.

### DETAILED DESCRIPTION OF THE EMBODIMENTS

Hereinafter, the present invention will be in detail explained with reference to the attached drawings. Objects, characteristics and advantages of the present invention will be more clearly understood from the detailed description as will be described below and the attached drawings. Before the present invention is disclosed and described, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one of ordinary skill in the art to variously employ the present invention in virtually any appropriately detailed structure. In the description, the corresponding parts in the embodiments of the present invention are indicated by corresponding reference numerals.

All terms used herein, including technical or scientific terms, unless otherwise defined, have the same meanings which are typically understood by those having ordinary skill in the art. The terms, such as ones defined in common dictionaries, should be interpreted as having the same meanings as terms in the context of pertinent technology, and should not be interpreted as having ideal or excessively formal meanings unless clearly defined in the specification. Terms used in this application are used to only describe specific exemplary embodiments and are not intended to restrict the present invention. An expression referencing a singular value additionally refers to a corresponding expression of the plural number, unless explicitly limited otherwise by the context.

In this application, terms, such as “comprise”, “include”, or “have”, are intended to designate those characteristics, numbers, steps, operations, elements, or parts which are described in the specification, or any combination of them that exist, and it should be understood that they do not preclude the possibility of the existence or possible addition of one or more additional characteristics, numbers, steps, operations, elements, or parts, or combinations thereof.

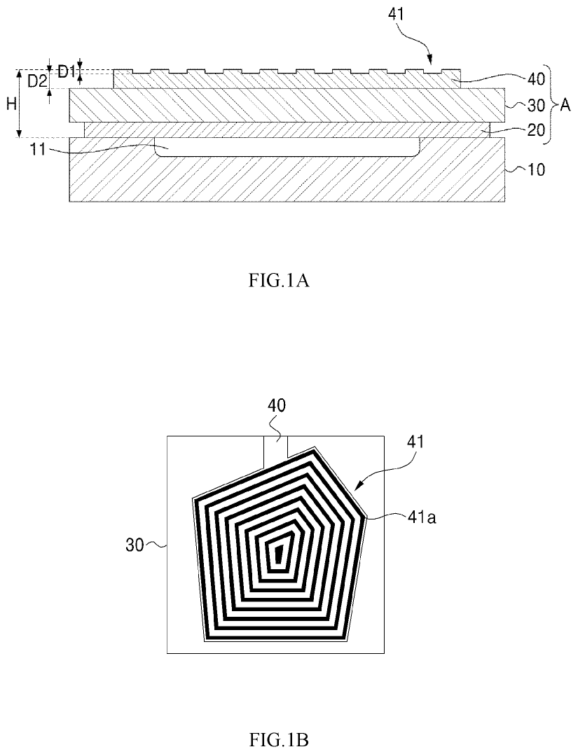

FIGS. 1A and 1B are sectional and top views showing a piezoelectric thin film resonator according to a first embodiment of the present invention.

Referring to FIG. 1A, first, a piezoelectric thin film resonator 100 according to a first embodiment of the present invention includes a wafer 10, a lower electrode 20, a piezoelectric layer 30, and an upper electrode 40.

The wafer 10 is made of a material capable of providing a piezoelectric effect, and for example, the wafer 10 is constituted of one selected from a silicon (Si) wafer, a high resistance silicon (HRS) wafer, a gallium arsenide (Ge—As) wafer, a diamond wafer, a sapphire wafer, a silicon carbide wafer, a LiNbO₃ wafer, and a LiTaO₃ wafer.

Next, the lower electrode 20 and the upper electrode 40 are located on the wafer 10. In more detail, a gap 11 is formed between the lower electrode 20 and the wafer 10, so that the lower electrode 20 can be spaced apart from a given portion of the wafer 10. Moreover, the gap 11 is formed on a portion where the lower electrode 20 and the upper electrode 40 are laid on each other with respect to a vertical direction, and as the gap 11 is formed between the lower electrode 20 and the wafer 10, loss of vibration energy generated after application of power can be reduced.

Further, the lower electrode 20 and the upper electrode 40 are made of metals having excellent electrical conductivity, such as molybdenum (Mo), ruthenium (Ru), rhodium (Rh), iridium (Ir), chromium (Cr), aluminum (Au), gold (Au), platinum (Pt), tungsten (W), tantalum (Ta), and titanium (Ti), and otherwise, they are made of materials laminated with a combination of the above-mentioned metals.

Next, the piezoelectric layer 30 is disposed between the lower electrode 20 and the upper electrode 40 to generate the piezoelectric effect. In more detail, if a high frequency electrical signal is applied between the lower electrode 20 and the upper electrode 40 to induce an electric field in the piezoelectric layer 30, the electric field causes the piezoelectric effect from the piezoelectric layer 30, so that the lower electrode 20, the piezoelectric layer 30, and the upper electrode 40 are vibrated in a given direction. Accordingly, a bulk acoustic wave is generated in the same direction as the vibrating direction, thereby producing resonance.

In detail, the resonance can be generated in a frequency

$$H = \frac{n λ}{2}$$

wherein a total thickness H of a vibration part A having the lower electrode 20, the piezoelectric layer 30, and the upper electrode 40 becomes an integer multiple (n times) as ½ of a wavelength λ of an elastic wave.

Also, if it is assumed that a propagation velocity of the elastic wave determined by the material of the piezoelectric layer 30 is V, a resonance frequency F is

$$F = \frac{nV}{2 H} ,$$

and accordingly, the resonance frequency F can be controlled by means of the total thickness H of the vibration part A, thereby obtaining the piezoelectric thin film resonator 100 having desired frequency characteristics.

So as to produce the resonance through the electric field, as mentioned above, the piezoelectric layer 30 is constituted of aluminum nitride (AlN), zinc oxide (ZnO), lead zirconate titanate (PZT), lead titanate (PbTiO₃), or the like.

Like this, an area where the lower electrode 20 and the upper electrode 40 face each other in such a manner as to place the piezoelectric layer 30 therebetween becomes a resonance area, and accordingly, if the vibration energy remains in the resonance area, the vibration characteristics of the piezoelectric thin film resonator can be improved. According to the first embodiment of the present invention, therefore, concavo-convex patterns are formed on top of the upper electrode 40 so as to allow the vibration energy to remain in the resonance area.

Referring to FIG. 1B, in more detail, the upper electrode 40 having a shape of a pentagon is placed on top of the piezoelectric layer 30, and concavo-convex patterns 41 are formed to surround a periphery of the upper electrode 40, that is, the resonance area. In this case, the concavo-convex patterns 41 have various shapes surrounding the resonance area, and for the convenience of the description, as shown in FIG. 1B, a plurality of pentagonal shapes corresponding to the shape of the resonance area is determined as first patterns 1a. However, the first patterns 41a may have round shapes, closed pentagonal shapes, and other shapes.

Like this, the first patterns 41a are formed on top of the upper electrode 40 in such a manner as to completely surround the resonance area, thereby suppressing elastic wave energy from leaking on the resonance area.

On the other hand, a vertical height D1 of the first patterns 41a formed on top of the upper electrode 40 is lower than a vertical height D2 of the upper electrode 40. In detail, if a ratio of the vertical height D1 of the first patterns 41a to the vertical height D2 of the upper electrode 40 is less than 1:20, the energy loss generated from the upper electrode 40 cannot be suppressed sufficiently, and further, insertion loss decreases at the time when a filter is made. Contrarily, if the ratio of the vertical height D1 of the first patterns 41a to the vertical height D2 of the upper electrode 40 is greater than 3:10, it is hard to make the first patterns 41a having desired thicknesses and heights on top of the upper electrode 40, thereby failing to ensure a process yield ratio. Accordingly, the ratio of the vertical height D1 of the first patterns 41a to the vertical height D2 of the upper electrode 40 is desirably 1:20 to 3:10.

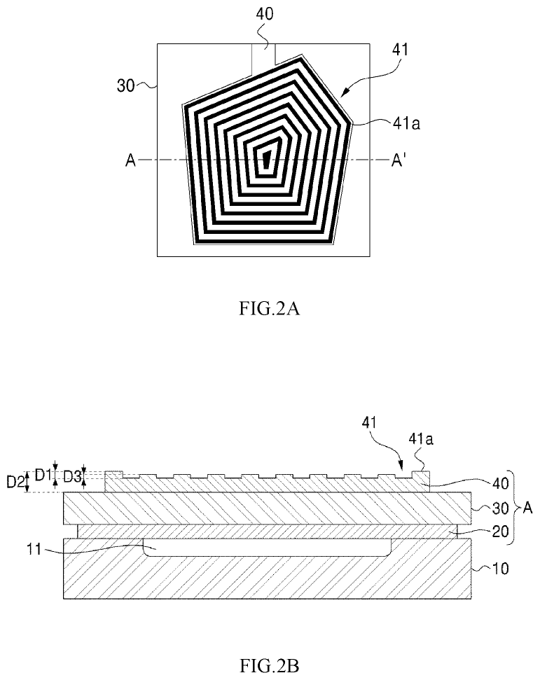

Like this, the range of the ratio of the vertical height D1 of the first patterns 41a to the vertical height D2 of the upper electrode 40 is defined, so that the first patterns 41a can be formed to different heights on the resonance area, which will be explained with reference to FIGS. 2A and 2B.

FIGS. 2A and 2B are top and sectional views showing a piezoelectric thin film resonator according to a second embodiment of the present invention.

Referring to FIG. 2A, an upper electrode 40 with first patterns 41a having shapes of the same pentagonal loops as in FIG. 1B is disposed on the resonance area. FIG. 2B shows the section of the piezoelectric thin film resonator taken along the line A-A′ of FIG. 2A. In detail, a vertical height D1 of the first pattern 41a formed along the outermost periphery of the resonance area is higher than vertical heights D3 of the first patterns 41a formed along the inner side of the resonance area.

If the vertical heights D3 of the first patterns 41a are smaller than the vertical height D1 of the first pattern 41a formed along the outermost periphery of the resonance area, like this, total mass M of the first patterns 41a is decreased so that the resonance frequency F can be adjusted. In more detail, the resonance frequency F according to the mass of the concave-convex patterns 41 can be adjusted with a relational expression like a first mathematical expression.

$$Total mass ( M ) of patterns ( 41 ) ∝ \frac{1}{Resonance frequency ( F )} \qquad [ First mathematical expression ]$$

In detail, the total mass M of the first patterns 41 is inversely proportional to the resonance frequency F, and accordingly, the heights of the first patterns 41 are differently formed inside the resonance area of the upper electrode 40, thereby appropriately adjusting the resonance frequency F.

Through the formation of the first patterns 41 on the resonance area, moreover, a large resonance frequency adjusting range can be ensured. According to the present invention, the resonance frequency F can have an adjusting range larger by 8 to 12% than that of the piezoelectric thin film resonator having no first patterns 41.

If the vertical height D1 of the first pattern 41a formed along the outermost periphery of the resonance area in the first patterns 41a having the shapes of the plurality of pentagonal loops is higher than the vertical heights D3 of the first patterns 41a formed along the inner side of the resonance area, as shown in FIG. 2B, spurious resonance may be generated by means of the elastic wave generated in a horizontal direction. Accordingly, the first patterns 41 formed on the resonance area of the upper electrode 40 have the highest height on the outermost periphery of the resonance area. Moreover, the spurious resonance may become residual resonance occurring on the area except the resonance area.

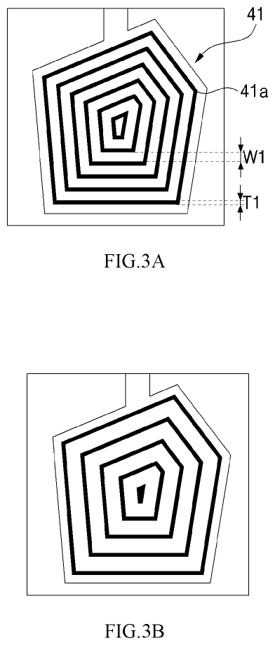

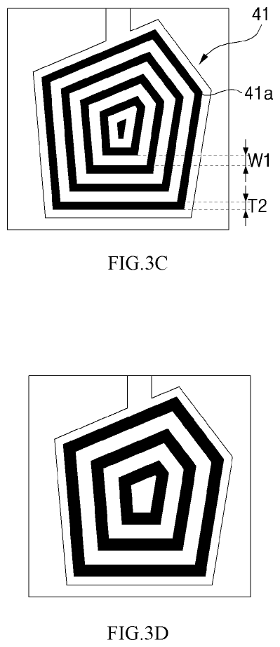

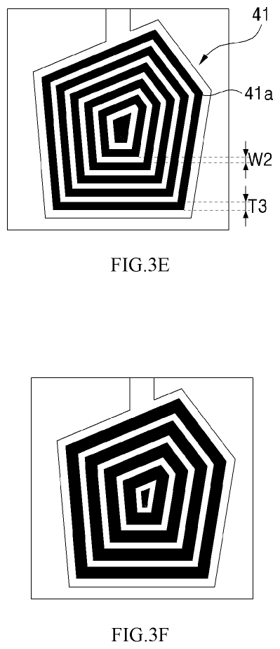

FIGS. 3A to 3F are top views showing various thicknesses and distances of the concavo-convex pattern on the upper electrode of the piezoelectric thin film resonator according to the first embodiment of the present invention.

Referring to FIGS. 3A and 3B, thicknesses T1 of the first patterns 41a of the concavo-convex patterns 40 formed on the resonance area of the upper electrode 40 are constant, but distances W1 thereof can be differently formed. As the distances W1 between the first patterns 41a having the same pentagonal shape as the resonance area are increased, in detail, the resonance frequency F can become increased.

Referring further to FIGS. 3C and 3D, the distances W1 of the first patterns 41a are constant, but thicknesses T2 thereof can be differently formed. As the thicknesses T2 of the first patterns 41a are increased, accordingly, the resonance frequency F can become decreased.

Referring furthermore to FIGS. 3E and 3F, distances W2 and thicknesses T3 of the first patterns 41a are differently formed, but the total mass of the first patterns 41a can be maintained. As a period of the wavelength λ of the elastic wave is varied, however, the resonance frequency F can be adjusted.

In detail, the piezoelectric thin film resonator 100 can have different resonance frequencies F according to the thicknesses or distances of the plurality of pentagonal patterns formed on the resonance area of the upper electrode 40.

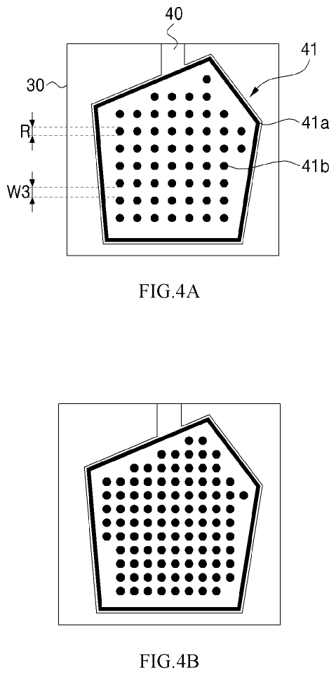

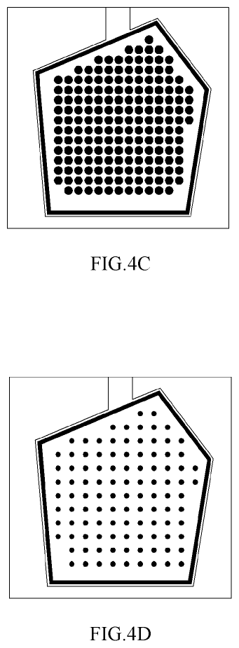

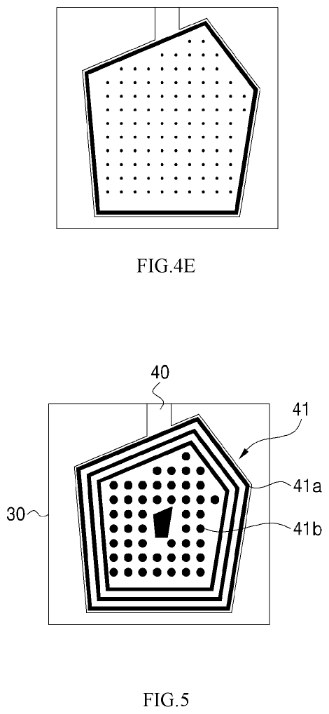

FIGS. 4A to 4E are top views showing examples of a concavo-convex pattern on an upper electrode of a piezoelectric thin film resonator according to a third embodiment of the present invention.

In addition to the plurality of round loops, referring to FIG. 4A, second patterns 41b having island-shaped patterns can be formed on the resonance area of the upper electrode 40. In more detail, the second patterns 41b have a plurality of island-shaped patterns, and at least one loop-shaped pattern is formed along the periphery of the resonance area. As the island-shaped patterns are formed, like this, the leakage of the elastic wave energy can be suppressed on the resonance area, and spurious noise can be reduced.

The island-shaped patterns in FIG. 4A to 4E have shapes of circles, but without being limited thereto, they may have shapes of polygons and rings.

Even in case of the second patterns 41b having the island-shaped patterns, also, the resonance frequency F can be different according to sizes (indicated by a diameter R) or densities of the island-shaped patterns.

Referring to FIGS. 4B and 4C, in more detail, as the densities of the island-shaped patterns are increased, that is, as the densities of the second patterns 41b are increased, the resonance frequency F can be decreased. Referring further to FIGS. 4D and 4E, as distances W3 of the island-shaped patterns are increased through the decrement in the sizes of the second patterns 41b, the densities of the second patterns 41b are decreased, so that the resonance frequency F can be increased.

FIG. 5 is a top view showing a concavo-convex pattern on an upper electrode of a piezoelectric thin film resonator according to a fourth embodiment of the present invention.

Referring to FIG. 5, the resonance frequency F of the piezoelectric thin film resonator according to the fourth embodiment of the present invention can be adjusted through the combination of the concavo-convex patterns 41 having various shapes.

In detail, the second patterns 41b as shown in FIGS. 4A to 4E are formed to have one loop-shaped pattern formed only along the outermost periphery of the resonance area, but as shown in FIG. 5, a plurality of loop-shaped patterns can be formed inside the outermost periphery of the resonance area. So as to obtain a desired value of the resonance frequency F, accordingly, the concavo-convex patterns 41 having various shapes can be formed on the resonance area of the upper electrode 40.

Meanwhile, the concavo-convex patterns 41 can be formed by means of a photolithography process, and through a variety of processes, otherwise, a layer of fine concavo-convex patterns 41 can be formed on top of the upper electrode 40.

Up to now, the shapes of the concavo-convex patterns 41 formed on the resonance area of the upper electrode 40 according to the various embodiments of the present invention have been explained. According to the present invention, the leakage of the elastic wave energy can be suppressed only through the formation of the concavo-convex patterns 41 surrounding the resonance area, thereby improving the characteristics of the piezoelectric thin film resonator, and an electromechanical coupling factor can be increased according to the shapes of the concavo-convex patterns 41, thereby reducing residual resonance (spurious noise) generated.

During a process where the upper electrode 40 is laminated, further, the concavo-convex patterns 41 can be simultaneously formed thereon, thereby improving the manufacturing efficiency of the piezoelectric thin film resonator 100.

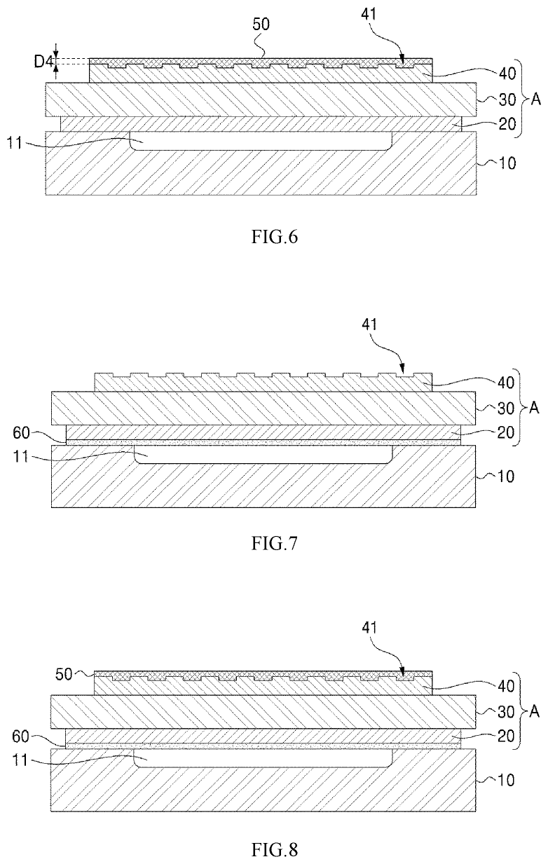

FIG. 6 is a sectional view showing a piezoelectric thin film resonator according to a fifth embodiment of the present invention, FIG. 7 is a sectional view showing a piezoelectric thin film resonator according to a sixth embodiment of the present invention, and FIG. 8 is a sectional view showing a piezoelectric thin film resonator according to a seventh embodiment of the present invention.

Referring to FIG. 6, a piezoelectric thin film resonator 100 according to a fifth embodiment of the present invention further includes a protection layer 50 adapted to cover the concavo-convex patterns 41 formed on the resonance area. In detail, the protection layer 50 serves to prevent the fine concavo-convex patterns 41 from being damaged and is made of an insulation material. For example, the material of the protection layer 50 is selected from silicon oxides, silicon nitrides, and aluminum nitrides.

If the protection layer 50 is formed, further, it can be included in the vibration part A, and accordingly, the resonance frequency F can be adjusted according to a vertical height D4 of the protection layer 50.

Referring next to FIG. 7, a piezoelectric thin film resonator 100 according to a sixth embodiment of the present invention further includes a seed layer 60 between the wafer 10 and the lower electrode 20. In a process where the lower electrode 20 is located on the wafer 10, in more detail, the seed layer 60 serves to increase a fixing force between the wafer 10 and the lower electrode 20 and to enhance crystallinity of the lower electrode 20 and the piezoelectric layer 30 to increase the piezoelectric effect.

To do this, further, the seed layer 60 is made of a crystalline material which is the same as the aluminum nitride (AlN) of the piezoelectric layer 30, and as the crystallinity of the piezoelectric layer 30 becomes excellent, an effective electromechanical coupling coefficient value K₁ becomes big, thereby improving the characteristics of the piezoelectric thin film resonator 100.

Referring lastly to FIG. 8, a piezoelectric thin film resonator 100 according to a seventh embodiment of the present invention further includes both of the protection layer 50 and the seed layer 60. If the vertical heights of the protection layer 50 and the seed layer 60 are too high, however, the characteristics of the piezoelectric layer 30 can be decreased, and accordingly, the protection layer 50 and the seed layer 60 are formed limitedly under the consideration of the respective heights.

As described above, the piezoelectric thin film resonator according to the present invention is configured to have the patterns formed on the resonance area of the upper electrode, thereby improving the value of the electromechanical coupling factor K² and reducing the spurious noise.

Further, the piezoelectric thin film resonator according to the present invention is configured to have the patterns formed along the periphery of the resonance area, thereby reducing an amount of energy leaking and improving the quality factor (Q factor) value thereof.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A piezoelectric thin film resonator comprising:
a wafer:
a lower electrode positioned on top of the wafer;
a piezoelectric layer positioned on top of the lower electrode; and
an upper electrode positioned on top of the piezoelectric layer,
wherein the upper electrode has concavo-convex patterns formed on top thereof in such a manner as to surround a resonance area formed thereon.

2. The piezoelectric thin film resonator according to claim 1, wherein the concavo-convex patterns comprise first patterns having shapes of a plurality of loops in such a manner as to surround a periphery of the resonance area.

3. The piezoelectric thin film resonator according to claim 2, wherein resonance frequencies thereof are varied according to thicknesses or distances of the first patterns having the shapes of the plurality of loops.

4. The piezoelectric thin film resonator according to claim 1, wherein the concavo-convex patterns comprise second patterns having shapes of a plurality of islands in such a manner as to surround a periphery of the resonance area.

5. The piezoelectric thin film resonator according to claim 4, wherein the concavo-convex patterns further comprise a pattern having a shape of a loop in such a manner as to surround the second patterns having the shapes of the plurality of islands.

6. The piezoelectric thin film resonator according to claim 4, wherein resonance frequencies thereof are varied according to sizes or densities of the second patterns having the shapes of the plurality of islands.

7. The piezoelectric thin film resonator according to claim 1, wherein a ratio of a vertical height of the first patterns to a vertical height of the upper electrode is 1:20 to 3:10.

8. The piezoelectric thin film resonator according to claims 1, wherein a vertical height of the concavo-convex patterns formed along the outermost periphery of the resonance area is higher than vertical heights of the concavo-convex patterns formed along the inner side of the resonance area.

9. The piezoelectric thin film resonator according to claim 1, further comprising a protection layer positioned on top of the upper electrode to cover an area where the concavo-convex patterns are formed.

10. The piezoelectric thin film resonator according to claim 1, further comprising a seed layer formed between the wafer and the lower electrode.
